(19) United States
(12) Patent Application Publication
(10) Pub. No.: US 2026/0157000 A1
(43) Pub. Date: Jun. 4, 2026

(54) DISPLAY DEVICE

(71) Applicant: AUO Corporation, Hsinchu City (TW)

(72) Inventor: Chia-Chuan Hsieh, Hsinchu City (TW)

(73) Assignee: AUO Corporation, Hsinchu City (TW)

(21) Appl. No.: 19/224,930

(22) Filed: Jun. 2, 2025

(30) Foreign Application Priority Data
Dec. 4, 2024 (TW) 113146901

(51) Int. Cl. H10H 29/49; H10H 29/01

(52) U.S. Cl. CPC H10H 29/49; H10H 29/012

(57) ABSTRACT

A display device includes a driving backplane and multiple light emitting diodes. The driving backplane includes a carrying base, an insulating structure, a first electrical connection material, a second electrical connection material, a first solder, a second solder. The insulating structure is set on the carrying base and has a first groove and a second groove. The first electrical connection material is located in the first groove. The second electrical connection material is located in the second groove. The first solder is located on the first electrical connection material. The second solder is located on the second electrical connection material. The light-emitting diode includes a first electrode and a second electrode. The first electrode is bonded to the first solder. The second electrode is bonded to the second solder. In a direction parallel to surface of the carrying substrate, the first and the second electrodes overlap with the insulating structure.

### CROSS-REFERENCE TO RELATED APPLICATION

This application claims the priority benefit of Taiwan application serial no. 113146901, filed on Dec. 4, 2024. The entirety of the above-mentioned patent application is hereby incorporated by reference herein and made a part of this specification.

### BACKGROUND

### Technical Field

The disclosure relates to an optoelectronic device, and particularly relates to a display device.

Related Art

The light-emitting diode display panel includes a driving backplane and multiple light-emitting diode elements transferred onto the driving backplane. Inheriting the characteristics of light-emitting diodes, the light-emitting diode display panel has advantages such as power saving, high efficiency, high brightness, and fast response time. In addition, compared with organic light-emitting diode display panels, light-emitting diode display panels also have advantages such as easy color adjustment, long illumination life, and no image imprinting. Therefore, light-emitting diode display panels are considered as the next generation display technology.

In the manufacturing process of the light-emitting diode display panel, multiple light-emitting diode elements on the temporary base should be mass transferred to the driving backplane, and the electrodes of the light-emitting diode elements must be electrically connected to the pads of the driving backplane. When transferring the light-emitting diode elements, laser may be used to irradiate the temporary base and light-emitting diode elements, such that the electrodes of the light-emitting diode elements and the pads of the driving backplane are eutectic bonded, and the light-emitting diode elements are separated from the base of the temporary base. However, during the process of laser irradiation on the temporary base, the adhesive layer of the temporary base is subjected to heat and thermal expansion occurs, causing the position of the light-emitting diode elements set on the adhesive layer of the temporary base to shift. The shift of the light-emitting diode elements may cause the solder to melt and remain in the gap between the two pads on the driving backplane to form a short circuit, which increases risk of subsequent debonding process.

### SUMMARY

The disclosure provides a display device with high yield.

A display device of the disclosure includes a driving backplane and a light-emitting diode. The driving backplane includes a carrying base; an insulating structure; a first electrical connection material; a second electrical connection material; a first solder; and a second solder. The insulating structure is set on the carrying base and has a first groove and a second groove. The first electrical connection material is located in the first groove. The second electrical connection material is located in the second groove. The first solder is located on the first electrical connection material. The second solder is located on the second electrical connection material. The light-emitting diode includes a first electrode and a second electrode. The first electrode is bonded to the first solder. The second electrode is bonded to the second solder. In a direction parallel to a surface of the carrying base, the first electrode and the second electrode overlap with the insulating structure.

In an embodiment of the disclosure, a melting point of the first solder and the second solder is lower than a melting point of the first electrode and the second electrode.

In an embodiment of the disclosure, a melting point of the first solder and the second solder is lower than a melting point of the first electrical connection material and the second electrical connection material.

In an embodiment of the disclosure, the insulating structure includes a first barrier surrounding the first groove, the insulating structure includes a second barrier surrounding the second groove, the first solder is recessed within the first barrier, and the second solder is recessed within the second barrier.

In an embodiment of the disclosure, there is a gap between an outer side of the first barrier and an outer side of the second barrier, which are correspondingly between the first electrode and the second electrode.

In an embodiment of the disclosure, an inner side of the first barrier is perpendicular to the carrying base, an outer side of the first barrier is tilted to the inner side, an inner side of the second barrier is perpendicular to the carrying base, and an outer side of the second barrier is tilted to the inner side.

In an embodiment of the disclosure, one side of the first barrier and one side of the second barrier, which are correspondingly between the first electrode and the second electrode, are directly connected.

In an embodiment of the disclosure, another side of the first barrier is tilted to the carrying base, and another side of the second barrier is tilted to the carrying base.

In an embodiment of the disclosure, a chemical nickel gold is provided between the first solder and the first electrical connection material and between the second solder and the second electrical connection material.

In an embodiment of the disclosure, the first electrode extends into the first solder and does not directly contact the first electrical connection material, and the second electrode extends into the second solder and does not directly contact the second electrical connection material.

Based on the above, in the display device of the disclosure, the insulating structure of the driving backplane has grooves, and the grooves are provided with electrical connection material and solders. Since the solder is located inside the groove, during the bonding process, the solder can be prevented from remaining in the gap between the two electrodes of the light-emitting diode, thereby avoiding short circuit between the two electrodes. Thereby, the bonding yield of the light-emitting diode and the driving backplane can be significantly improved.

The accompanying drawings are included to provide a further understanding of the disclosure, and are incorporated in and constitute a part of this specification. The drawings illustrate embodiments of the disclosure and, together with the description, serve to explain the principles of the disclosure.

### BRIEF DESCRIPTION OF THE DRAWINGS

FIG. 1 is a schematic view of a bonding process of a display device according to an embodiment of the disclosure.

FIG. 2 is a perspective schematic view of the display device according to an embodiment of the disclosure.

FIG. 3 is a top view of the display device of FIG. 2.

FIG. 4A is a cross-sectional view of the display device of FIG. 3.

FIG. 4B to FIG. 4D are cross-sectional views of the display devices according to multiple embodiments of the disclosure.

FIG. 5 is a schematic view of the bonding process of the display device according to an embodiment of the disclosure.

FIG. 6A to FIG. 6D are cross-sectional views of the display devices according to multiple embodiments of the disclosure.

### DESCRIPTION OF THE EMBODIMENTS

The disclosure will be described more fully hereinafter with reference to the accompanying drawings, in which exemplary embodiments of the disclosure are shown. As will be appreciated by those skilled in the art, the embodiments described may be modified in various different ways without departing from the spirit or scope of the disclosure.

In the drawings, the thickness of layers, films, panels, regions, etc. are exaggerated for clarity. Throughout the specification, the same reference numerals denote the same elements. It should be understood that when an element such as a layer, film, region, or substrate is referred to as being “on” or “connected to” another element, it may be directly on or connected to the other element, or intervening elements may be present. In contrast, when an element is referred to as being “directly on” or “directly connected to” another element, there are no intervening elements present. As used herein, “connected” may refer to physical and/or electrical connection. Furthermore, “electrical connection” or “coupling” may exist between two elements with other elements between them.

In addition, relative terms such as “below” or “bottom” and “above” or “top” may be used herein to describe a relationship of one element to another element as shown in the drawings. It should be understood that the relative terms are intended to encompass different orientations of the device in addition to the orientation depicted in the drawings. For example, if a device in one of the figures is turned over, an element having been described as being on the “below” side of other elements would be oriented on the “above” side of the other elements. Thus, the exemplary term “below” may encompass both “below” and “above” orientations, depending on the particular orientation of the drawing. Similarly, if a device in one of the drawings is turned over, an element having been described as “under” or “below” other elements would be oriented “above” the other elements. Thus, the exemplary terms “above” or “below” may encompass both above and below orientations.

The terms “about,” “approximately,” or “substantially” as used herein include the stated value and average value within an acceptable range of deviation for the particular value as determined by one of ordinary skill in the art, taking into consideration the particular amount of the measurements in question and errors associated with the measurements (i.e. the limitations of the measurement system). For example, “about” may indicate within one or more standard deviations of the stated value, or within ±30%, ±20%, ±10%, ±5%. Furthermore, “about,” “approximately,” or “substantially” as used herein may be selected according to more acceptable deviation ranges or standard deviations based on optical properties, etching properties, or other properties, rather than using one standard deviation for all properties.

Example embodiments are described herein with reference to cross-sectional diagrams that are schematic illustrations of idealized embodiments. As such, variations from the shapes of the illustrations as a result of, for example, manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawings are schematic in nature and their shapes are not intended to illustrate the precise shape of a region and are not intended to limit the scope of the claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

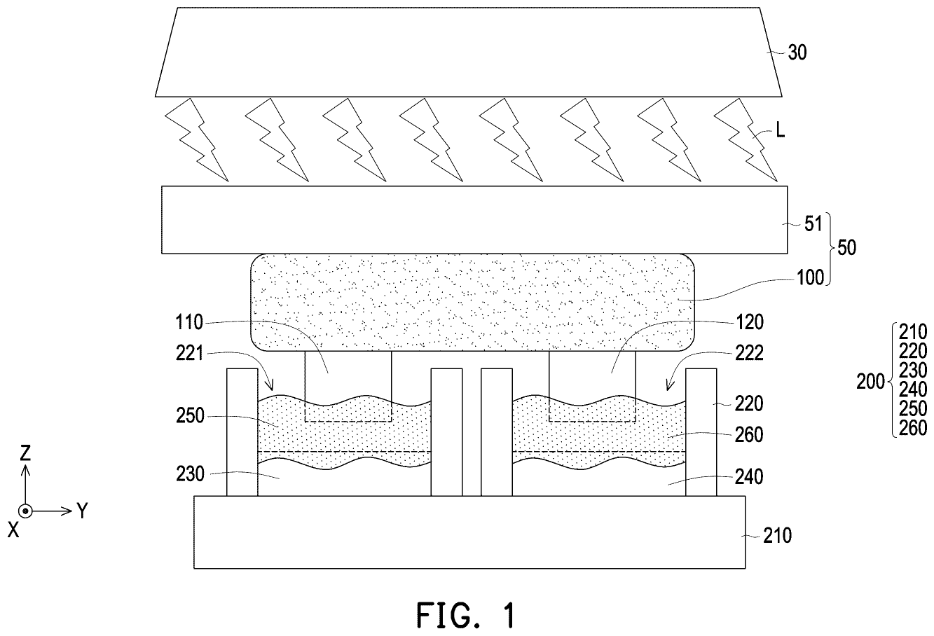

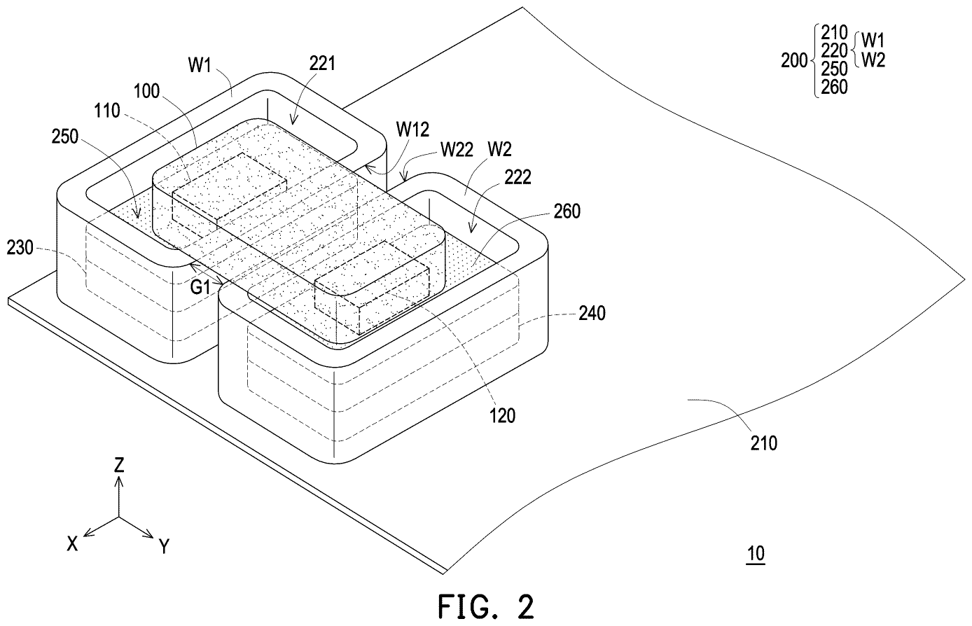

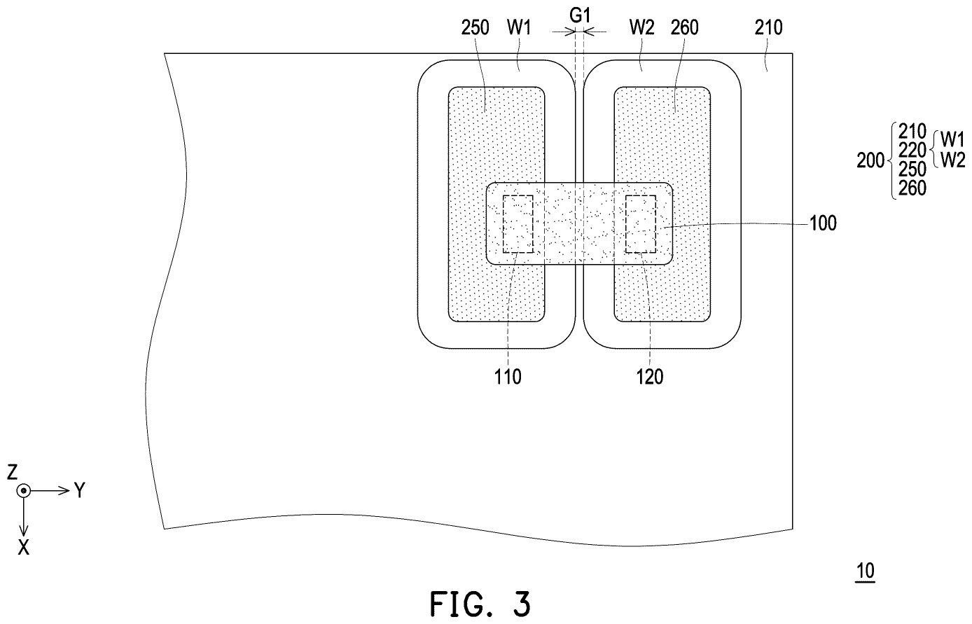

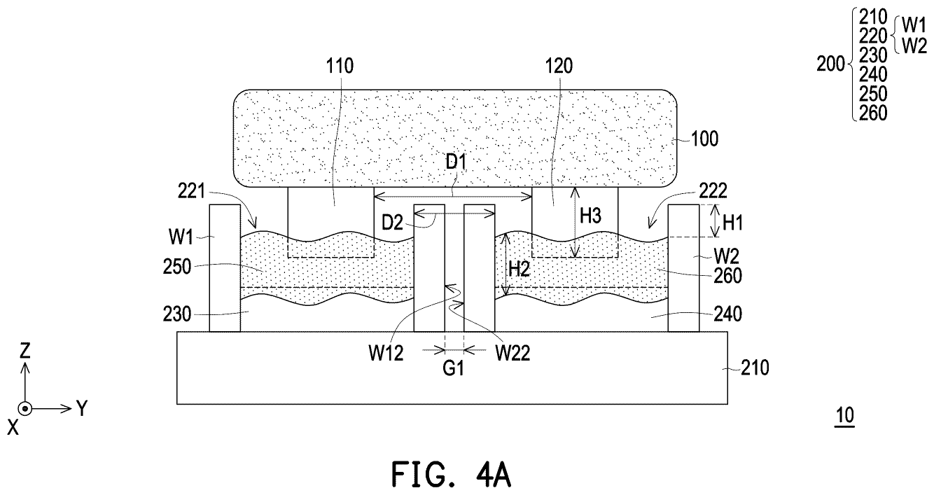

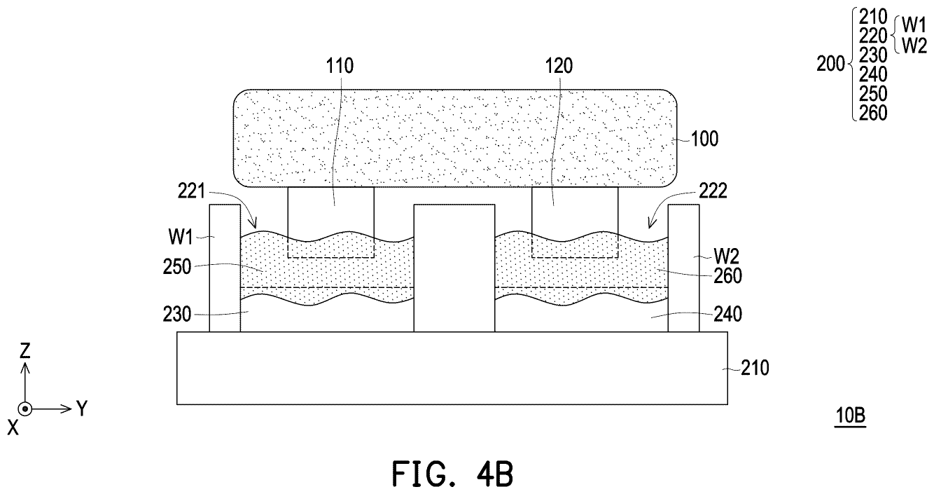

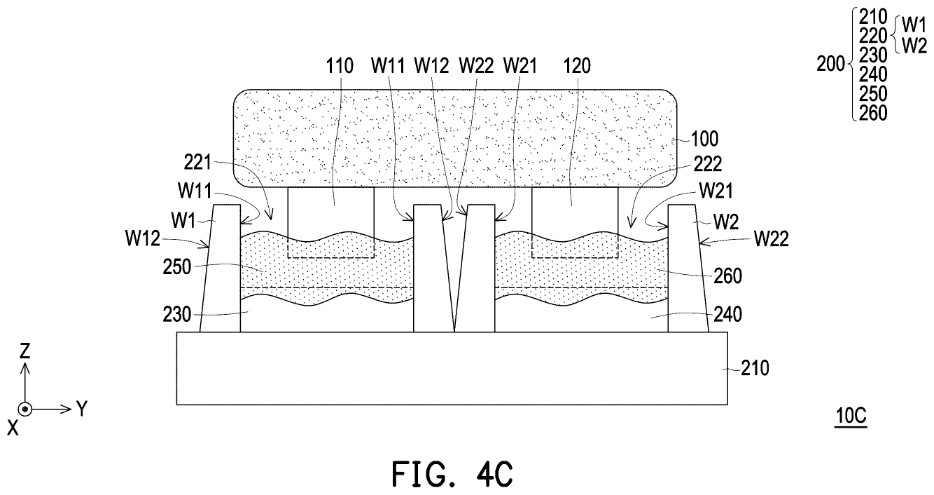

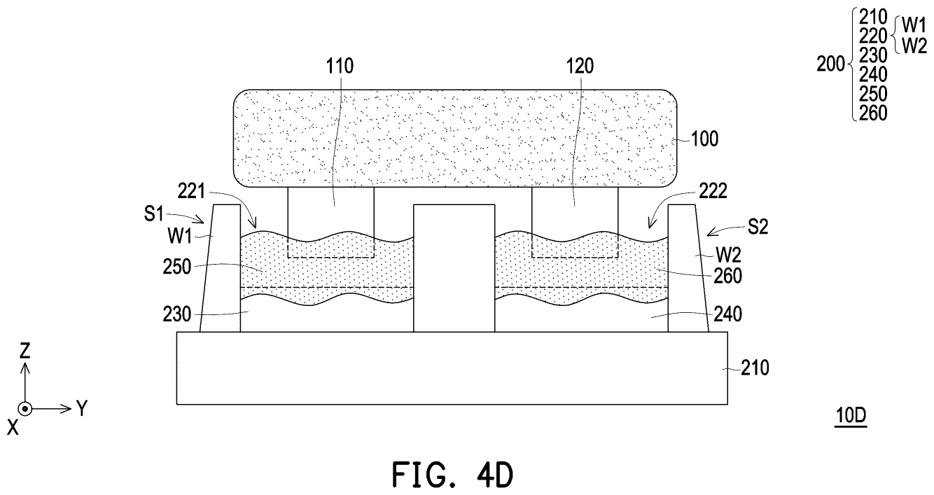

FIG. 1 is a schematic view of a bonding process of a display device according to an embodiment of the disclosure. FIG. 2 is a perspective schematic view of the display device according to an embodiment of the disclosure. FIG. 3 is a top view of the display device of FIG. 2. FIG. 4A is a cross-sectional view of the display device of FIG. 3. Note that X direction, Y direction, and Z direction are marked in the drawings to present the configuration relationship of each element in the drawings, where X direction, Y direction, and Z direction intersect with each other, but the disclosure is not limited thereto.

Referring to FIG. 1, first, a driving backplane 200 is provided. The driving backplane 200 includes a carrying base 210, an insulating structure 220, a first electrical connection material 230, a second electrical connection material 240, a first solder 250, and a second solder 260.

In this embodiment, the insulating structure 220 is set on the carrying base 210, and has a first groove 221 and a second groove 222. The first electrical connection material 230 is located in the first groove 221. The second electrical connection material 240 is located in the second groove 222. The first solder 250 is located on the first electrical connection material 230. The second solder 260 is located on the second electrical connection material 240.

For example, the insulating structure 220 may be a UHA layer or BP layer, with the outermost layer being tin plating, but the disclosure is not limited thereto.

For example, the material of the first electrical connection material 230 and the second electrical connection material 240 may include copper (Cu), but the disclosure is not limited thereto.

For example, the material of the first solder 250 and the second solder 260 may include tin (Sn), but the disclosure is not limited thereto. In other embodiments, the material of the first solder 250 and the second solder 260 may also be metals with lower melting points: In, Sn—Ag, Sn—Ag—In, or Sn—Ag—Bi, but the disclosure is not limited thereto.

Next, an illuminating element substrate 50 is provided. The illuminating element substrate 50 includes a temporary base 51 and a light-emitting diode 100. The temporary base 51 and the light-emitting diode 100 are fixed through an adhesive layer, but the disclosure is not limited thereto.

For example, in this embodiment, the driving backplane 200 further includes a pixel drive circuit. The pixel drive circuit may include a data line, a scan line, a power line, a common line, a first transistor, a second transistor, and a capacitor, wherein a first terminal of the first transistor is electrically connected to the data line, a control terminal of the first transistor is electrically connected to the scan line, a second terminal of the first transistor is electrically connected to a control terminal of the second transistor, a first terminal of the second transistor is electrically connected to the power line, the capacitor is electrically connected to the second terminal of the first transistor and the first terminal of the second transistor, a second terminal of the second transistor is electrically connected to one of the first electrical connection material 230 and the second electrical connection material 240, and the common line is electrically connected to the other one of the first electrical connection material 230 and the second electrical connection material 240. However, the disclosure is not limited thereto. In other embodiments, the pixel drive circuit may also be other types of circuits.

As shown in FIG. 1, the light-emitting diode 100 is transferred onto the driving backplane 200, and the light-emitting diode 100 is electrically connected to the driving backplane 200. Specifically, during part of the process of transferring the light-emitting diode 100 onto the driving backplane 200, a first electrode 110 of the light-emitting diode 100 extends into the first solder 250 and does not directly contact the first electrical connection material 230, and a second electrode 120 of the light-emitting diode 100 extends into the second solder 260 and does not directly contact the second electrical connection material 240. For example, the material of the first electrode 110 and the second electrode 120 may include gold (Au), but the disclosure is not limited thereto.

In detail, in this embodiment, an infrared laser (IR Laser) illumination instrument 30 may emit a laser L. The laser L penetrates through the temporary base 51 and the light-emitting diode 100 and irradiates the first solder 250 and the first electrical connection material 230 in the first groove 221, and the second solder 260 and the second electrical connection material 240 in the second groove 222. The first solder 250 is eutectic bonded with the first electrical connection material 230 below it and also eutectic bonded with the first electrode 110 above it. The second solder 260 is eutectic bonded with the second electrical connection material 240 below it and also is eutectic bonded with the second electrode 120 above it, such that the first electrode 110 and the second electrode 120 of the light-emitting diode 100 are bonded with the driving backplane 200.

In this embodiment, the melting point of the first solder 250 and the second solder 260 is lower than the melting point of the first electrode 110 and the second electrode 120. The melting point of the first solder 250 and the second solder 260 is lower than the melting point of the first electrical connection material 230 and the second electrical connection material 240.

As a result, the first electrode 110 and the second electrode 120 of the light-emitting diode 100 may be effectively encapsulated by the molten solder (for example, Sn), increasing the contact area for eutectic reaction. For example, the bottom surface and side surface of the first electrode 110 and the second electrode 120 of the light-emitting diode 100 may contact the molten solder (for example, Sn), allowing sufficient time for Sn—Au to form a strong eutectic.

Under such configuration, the first solder 250 and the second solder 260 are respectively located in the first groove 221 and the second groove 222, which may prevent overflow of the first solder 250 and the second solder 260 during the laser process. Thereby, the bonding yield between the light-emitting diode 100 and the driving backplane 200 can be significantly improved.

Furthermore, when the light-emitting diode 100 is bonded with the driving backplane 200, the adhesive layer interface between the light-emitting diode 100 and the temporary base 51 irradiated by the laser L will be dissociated, causing the light-emitting diode 100 to separate from the temporary base 51 and be transferred to the driving backplane 200, thereby forming a display device 10 of FIG. 2, FIG. 3 and FIG. 4A. Note that the number of light-emitting diodes 100 on the driving backplane 200 is illustratively shown as one, but in practice, there are multiple light-emitting diodes 100 on the driving backplane 200 to facilitate mass transfer, and the disclosure is not limited thereto.

Referring to FIG. 2, FIG. 3 and FIG. 4A, in this embodiment, in a direction parallel to the surface of the carrying base 210, the first electrode 110 and the second electrode 120 overlap with the insulating structure 220. That is, in the Y direction and X direction, the first electrode 110 and the second electrode 120 overlap with the insulating structure 220. Thereby, the first electrode 110 and the second electrode 120 are respectively confined in the first groove 221 and the second groove 222, making them less likely to be displaced due to deformation of the solder underneath when heated.

Specifically, in this embodiment, the insulating structure 220 includes a first barrier W1 surrounding the first groove 221. The insulating structure 220 includes a second barrier W2 surrounding the second groove 222. The first solder 250 is recessed within the first barrier W1, and the second solder 260 is recessed within the second barrier W2.

In this embodiment, there is a gap G1 between an outer side W12 of the first barrier W1 and an outer side W22 of the second barrier W2, which are correspondingly between the first electrode 110 and the second electrode 120, but the disclosure is not limited to this.

In addition, in this embodiment, in the Z direction, the total height of the barrier minus the height of the solder and the electrical connection material is height H1, the solder has a height H2, and the electrode has a height H3. For example, in one embodiment, H1+H2>H3, which is capable of ensuring that the first electrode 110 does not directly contact the first electrical connection material 230, and the second electrode 120 does not directly contact the second electrical connection material 240. For example, in one embodiment, H3>H1, such that the first electrode 110 and the second electrode 120 are suitable for insertion into the first groove 221 and the second groove 222 formed by the first barrier W1 and the second barrier W2, respectively.

In the Y direction, there is a distance D1 between the first electrode 110 and the second electrode 120, and a distance D2 between the first barrier W1 and the second barrier W2. The distance D1 is greater than the distance D2, which can prevent short circuit.

The following lists other embodiments for illustration. The following embodiments use the reference numerals and partial content from the previous embodiments, where the same numbers are used to represent the same or similar elements, and explanations of identical technical content are omitted. For description of the omitted parts, please refer the previous embodiments, as they will not be repeated in the following embodiments.

FIG. 4B to FIG. 4D are cross-sectional views of the display devices according to multiple embodiments of the disclosure. Referring to FIG. 4B, in this embodiment, a display device 10B is slightly different from the display device 10 in FIG. 4A, with the main difference being: one side of the first barrier W1 and one side of the second barrier W2, which are correspondingly between the first electrode 110 and the second electrode 120, are directly connected. The advantage of this design is that a middle insulation layer may be shared, making the array process easier to implement.

Referring to FIG. 4C, in this embodiment, a display device 10C is slightly different from the display device 10 in FIG. 4A, with the main difference being: an inner side W11 of the first barrier W1 is perpendicular to the carrying base 210, the outer side W12 of the first barrier W1 is tilted to the inner side W11 of the first barrier W1, an inner side W21 of the second barrier W2 is perpendicular to the carrying base 210, and the outer side W22 of the second barrier W2 is tilted to the inner side W21 of the second barrier W2.

Referring to FIG. 4D, in this embodiment, one side of the first barrier W1 and one side of the second barrier W2, which are correspondingly between the first electrode 110 and the second electrode 120, are directly connected. Another side S1 of the first barrier W1 is tilted to the carrying base 210, and another side S2 of the second barrier W2 is tilted to the carrying base 210. The advantage of this design is that in a display device 10D, a middle insulation layer may be shared, making the array process easier to implement.

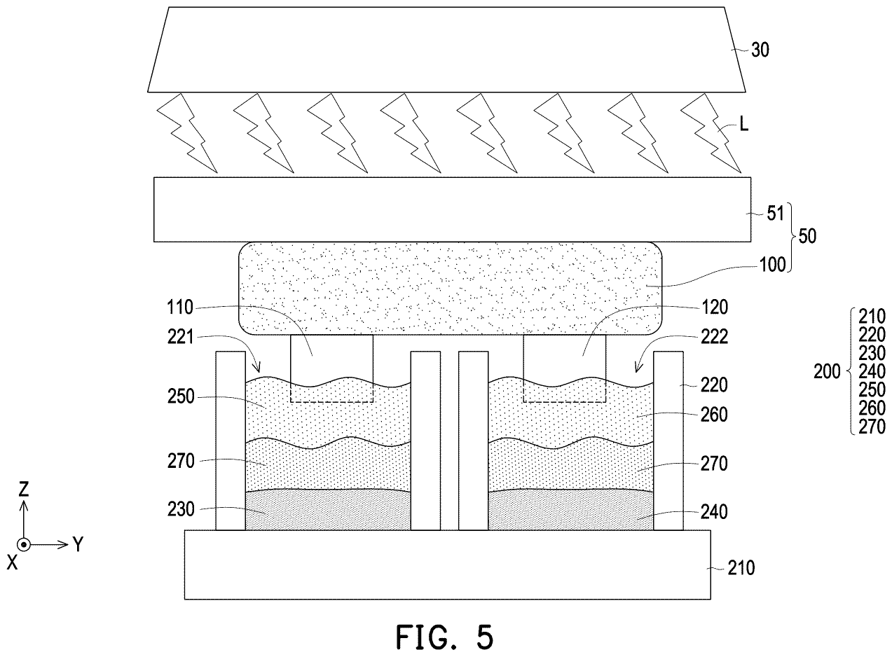

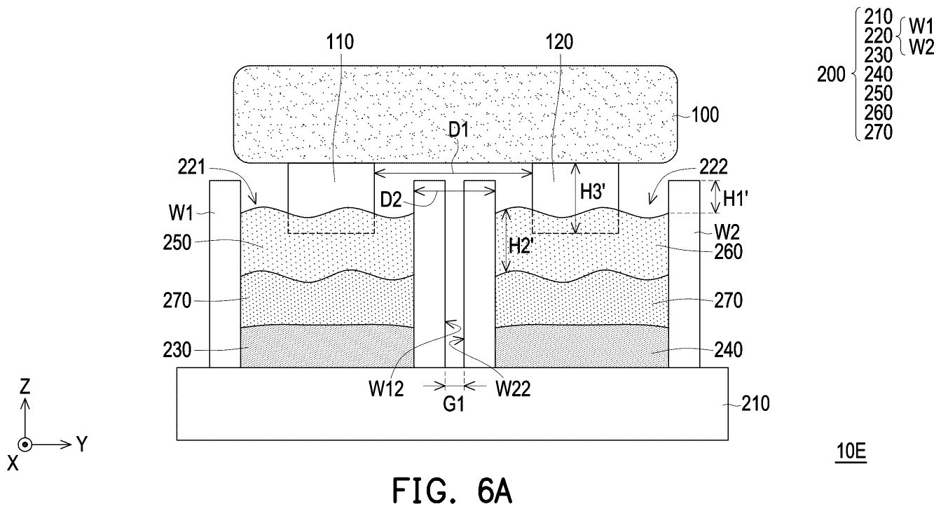

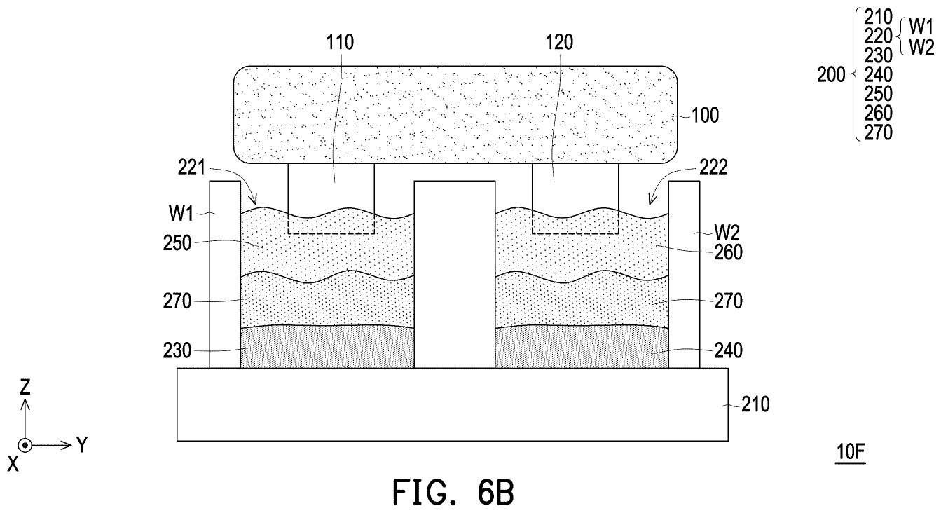

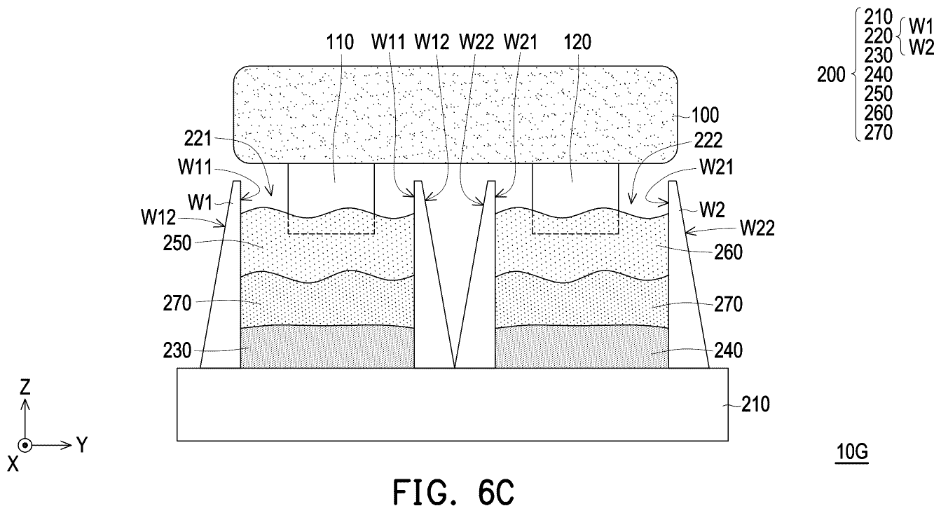

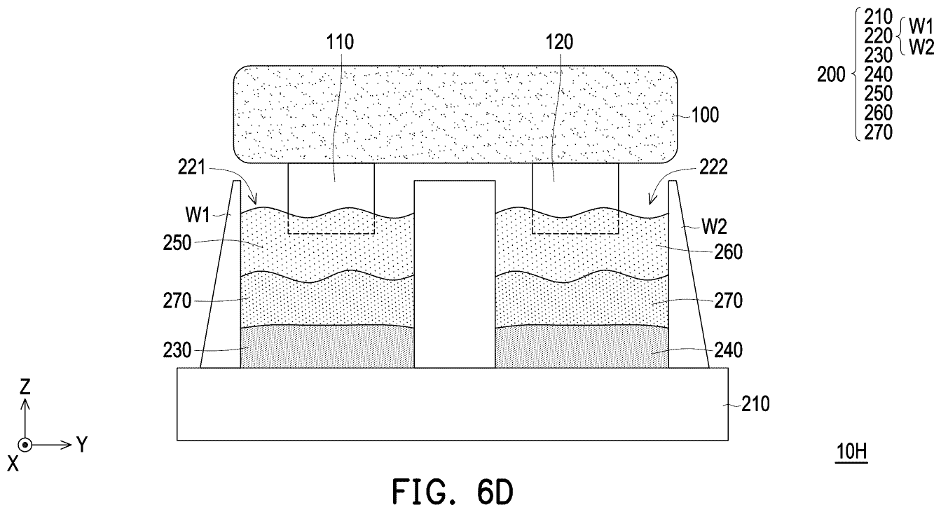

FIG. 5 is a schematic view of the bonding process of the display device according to an embodiment of the disclosure. FIG. 6A to FIG. 6D are cross-sectional views of the display devices according to multiple embodiments of the disclosure. Referring to FIG. 5 and FIG. 6A, in this embodiment, a display device 10E is slightly different from the display device 10 in FIG. 4A, with the main difference being: chemical nickel gold 270 is provided between the first solder 250 and the first electrical connection material 230, and between the second solder 260 and the second electrical connection material 240.

The chemical nickel gold 270 is capable of protecting the first electrical connection material 230 and the second electrical connection material 240 underneath, preventing oxidation. It may also form a eutectic with the first solder 250 and the second solder 260.

Referring to FIG. 6A, in this embodiment, in the Z direction, the total height of the barrier minus the height of the solder and the electrical connection material is height H1′, the solder has a height H2′, and the electrode has a height H3′. For example, in one embodiment, H1′+H2′>H3′, such that the first electrode 110 does not directly contact the first electrical connection material 230, and the second electrode 120 does not directly contact the second electrical connection material 240. For example, in one embodiment, H3′>H1′, such that the first electrode 110 and the second electrode 120 are suitable for insertion into the first groove 221 and the second groove 222 formed by the first barrier W1 and the second barrier W2, respectively.

In the Y direction, there is a distance D1 between the first electrode 110 and the second electrode 120, and a distance D2 between the first barrier W1 and the second barrier W2. The distance D1 is greater than the distance D2, which can prevent short circuit.

Referring to FIG. 6B, in this embodiment, a display device 10F is slightly different from the display device 10E in FIG. 6A, with the main difference being: one side of the first barrier W1 and one side of the second barrier W2, which are correspondingly between the first electrode 110 and the second electrode 120, are directly connected. The advantage of this design is that a middle insulation layer may be shared, making the array process easier to implement.

Referring to FIG. 6C, in this embodiment, a display device 10G is slightly different from the display device 10E in FIG. 6A, with the main difference being: the inner side W11 of the first barrier W1 is perpendicular to the carrying base 210, the outer side W12 of the first barrier W1 is tilted to the inner side W11 of the first barrier W1, the inner side W21 of the second barrier W2 is perpendicular to the carrying base 210, and the outer side W22 of the second barrier W2 is tilted to the inner side W21 of the second barrier W2.

Referring to FIG. 6D, in this embodiment, one side of the first barrier W1 and one side of the second barrier W2, which are correspondingly between the first electrode 110 and the second electrode 120, are directly connected. Another side S1 of the first barrier W1 is tilted to the carrying base 210, and another side S2 of the second barrier W2 is tilted to the carrying base 210. The advantage of this design is that in a display device 10H, a middle insulation layer may be shared, making the array process easier to implement.

In summary, in the display device of this disclosure, the insulating structure of the driving backplane has grooves, and the grooves are provided with electrical connection material and solder. Since the solder is located within the grooves, during the bonding process, the first electrode and the second electrode of the light-emitting diode may be effectively encapsulated by the molten solder, increasing the contact area for eutectic reaction. The first solder and the second solder are located in the first groove and the second groove respectively, which may prevent overflow of the first solder and the second solder due to the laser process. In the direction parallel to the surface of the carrying base, the first electrode and the second electrode overlap with the insulating structure, and the first electrode and the second electrode are respectively confined in the first groove and the second groove, making them less likely to be displaced due to deformation of the solder underneath when heated. Thereby, the bonding yield of the light-emitting diode and the driving backplane can be significantly improved.

It will be apparent to those skilled in the art that various modifications and variations may be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A display device, comprising:
a driving backplane, including:
a carrying base;
an insulating structure, set on the carrying base and having a first groove and a second groove;
a first electrical connection material, located in the first groove;
a second electrical connection material, located in the second groove;
a first solder, located on the first electrical connection material; and
a second solder, located on the second electrical connection material; and
a light-emitting diode, including:
a first electrode, bonded to the first solder; and
a second electrode, bonded to the second solder, wherein in a direction parallel to a surface of the carrying base, the first electrode and the second electrode overlap with the insulating structure.

2. The display device according to claim 1,
wherein a melting point of the first solder and the second solder is lower than a melting point of the first electrode and the second electrode.

3. The display device according to claim 1,
wherein a melting point of the first solder and the second solder is lower than a melting point of the first electrical connection material and the second electrical connection material.

4. The display device according to claim 1,
wherein the insulating structure includes a first barrier surrounding the first groove, the insulating structure includes a second barrier surrounding the second groove, the first solder is recessed within the first barrier, and the second solder is recessed within the second barrier.

5. The display device according to claim 4,
wherein there is a gap between an outer side of the first barrier and an outer side of the second barrier, which are correspondingly between the first electrode and the second electrode.

6. The display device according to claim 4,
wherein an inner side of the first barrier is perpendicular to the carrying base, an outer side of the first barrier is tilted to the inner side, an inner side of the second barrier is perpendicular to the carrying base, and an outer side of the second barrier is tilted to the inner side.

7. The display device according to claim 4,
wherein one side of the first barrier and one side of the second barrier, which are correspondingly between the first electrode and the second electrode, are directly connected.

8. The display device according to claim 7,
wherein another side of the first barrier is tilted to the carrying base, and another side of the second barrier is tilted to the carrying base.

9. The display device according to claim 1,
wherein a chemical nickel gold is provided between the first solder and the first electrical connection material and between the second solder and the second electrical connection material.

10. The display device according to claim 1,
wherein the first electrode extends into the first solder and does not directly contact the first electrical connection material, and the second electrode extends into the second solder and does not directly contact the second electrical connection material.

11. A method of making a display device, comprising:
providing a driving backplane, the driving backplane including a carrying base, an insulating structure, a first electrical connection material, a second electrical connection material, a first solder and a second solder, wherein the insulating structure is set on the carrying base and has a first groove and a second groove, the first electrical connection material is located in the first groove, the second electrical connection material is located in the second groove, the first solder is located on the first electrical connection material, and the second solder is located on the second electrical connection material;
providing a substrate, the substrate including a temporary base and a light-emitting diode, wherein the light-emitting diode includes a first electrode and a second electrode;
bonding the first electrode to the first solder and bonding the second electrode to the second solder, wherein in a direction parallel a surface of the carrying base, the first electrode and the second electrode overlap with the insulating structure; and
using laser irradiation to make the first electrode and the second electrode of the light-emitting diode eutectic bond with the driving backplane, and to separate the light-emitting diode from the temporary base.

12. The method of making a display device according to claim 11,
wherein a melting point of the first solder and the second solder is lower than a melting point of the first electrode and the second electrode.

13. The method of making a display device according to claim 11,
wherein a melting point of the first solder and the second solder is lower than a melting point of the first electrical connection material and the second electrical connection material.

14. The method of making a display device according to claim 11,
wherein the insulating structure includes a first barrier surrounding the first groove, the insulating structure includes a second barrier surrounding the second groove, the first solder is recessed within the first barrier, the second solder is recessed within the second barrier.

15. The method of making a display device according to claim 14,
wherein there is a gap between an outer side of the first barrier and an outer side of the second barrier, which are correspondingly between the first electrode and the second electrode.

16. The method of making a display device according to claim 14,
wherein an inner side of the first barrier is perpendicular to the carrying base, an outer side of the first barrier is tilted to the inner side, an inner side of the second barrier is perpendicular to the carrying base, and an outer side of the second barrier is tilted to the inner side.

17. The method of making a display device according to claim 14,
wherein one side of the first barrier and one side of the second barrier, which are correspondingly between the first electrode and the second electrode, are directly connected.

18. The method of making a display device according to claim 17,
wherein another side of the first barrier is tilted to the carrying base, and another side of the second barrier is tilted to the carrying base.

19. The method of making a display device according to claim 11,
wherein a chemical nickel gold is provided between the first solder and the first electrical connection material and between the second solder and the second electrical connection material.

20. The method of making a display device according to claim 11,
wherein the first electrode extends into the first solder and does not directly contact with the first electrical connection material, and the second electrode extends into the second solder and does not directly contact with the second electrical connection material.
